(19) United States
(12) Patent Application Publication
(10) Pub. No.: US 2025/0286339 A1
(43) Pub. Date: Sep. 11, 2025

(54) LINE NARROWING MODULE, LASER DEVICE, AND ELECTRONIC DEVICE MANUFACTURING METHOD

(71) Applicant: Gigaphoton Inc., Tochigi (JP)

(72) Inventor: Keita KOUZAI, Oyama-shi (JP)

(73) Assignee: Gigaphoton Inc., Tochigi (JP)

(21) Appl. No.: 19/045,838

(22) Filed: Feb. 5, 2025

(30) Foreign Application Priority Data
Mar. 11, 2024 (JP) 2024-037658

(51) Int. Cl. H01S 3/137; G03F 7/20; H01S 3/081; H01S 3/225

(52) U.S. Cl. CPC H01S 3/137; G03F 7/2006; G03F 7/2008; H01S 3/0812; H01S 3/225

(57) ABSTRACT

A line narrowing module to line-narrow pulse laser light having a wavelength in an ultraviolet range includes a grating reflecting pulse laser light incident thereon, and an expansion optical system including prisms and causing the pulse laser light to be incident on the grating while expanding a beam width of the pulse laser light. In the expansion optical system, a first closest prism which is closest to the grating and a second closest prism which is second closest to the grating have temperature coefficients of refractive indices opposite in sign to each other, and an amount of change of an optical path length difference between a case in which a temperature difference in the second closest prism is 0.2° C. or less and a case in which the temperature difference is 0.5° C. or more and 10° C. or less is half or less of the wavelength of the pulse laser light.

### CROSS-REFERENCE TO RELATED APPLICATIONS

The present application claims the benefit of Japanese Patent Application No. 2024-037658, filed on Mar. 11, 2024, the entire contents of which are hereby incorporated by reference.

### BACKGROUND

### 1. Technical Field

The present disclosure relates to a line narrowing module, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: International Publication No. WO2006/060360
Patent Document 2: European Patent Application Publication No. 1041689

### SUMMARY

A line narrowing module, according to an aspect of the present disclosure, to line-narrow pulse laser light having a wavelength in an ultraviolet range, includes a grating configured to reflect pulse laser light incident thereon, and an expansion optical system including a plurality of prisms and configured to cause the pulse laser light to be incident on the grating while expanding a beam width of the pulse laser light. In the expansion optical system, a first closest prism which is closest to the grating and a second closest prism which is second closest to the grating have temperature coefficients of refractive indices opposite in sign to each other, and an amount of change of an optical path length difference between a case in which a temperature difference in the second closest prism is 0.2° C. or less and a case in which the temperature difference is 0.5° C. or more and 10° C. or less is half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.

A laser device according to an aspect of the present disclosure includes a line narrowing module configured to line-narrow pulse laser light having a wavelength in an ultraviolet range, an output coupling mirror, and a laser chamber including a pair of discharge electrodes and arranged on an optical path of an optical resonator configured by the line narrowing module and the output coupling mirror. Here, the line narrowing module includes a grating configured to reflect pulse laser light incident thereon, and an expansion optical system including a plurality of prisms and configured to cause the pulse laser light to be incident on the grating while expanding a beam width of the pulse laser light. In the expansion optical system, a first closest prism which is closest to the grating and a second closest prism which is second closest to the grating have temperature coefficients of refractive indices opposite in sign to each other, and an amount of change of an optical path length difference between a case in which a temperature difference in the second closest prism is 0.2° C. or less and a case in which the temperature difference is 0.5° C. or more and 10° C. or less is half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.

An electronic device manufacturing method according to an aspect of the present disclosure includes generating pulse laser light using a laser device, outputting the pulse laser light to an exposure apparatus, and exposing a photosensitive substrate to the pulse laser light in the exposure apparatus to manufacture an electronic device. Here, the laser device includes a line narrowing module configured to line-narrow pulse laser light having a wavelength in an ultraviolet range, an output coupling mirror, and a laser chamber including a pair of discharge electrodes and arranged on an optical path of an optical resonator configured by the line narrowing module and the output coupling mirror. The line narrowing module includes a grating configured to reflect the pulse laser light incident thereon, and an expansion optical system including a plurality of prisms and configured to cause the pulse laser light to be incident on the grating while expanding a beam width of the pulse laser light. In the expansion optical system, a first closest prism which is closest to the grating and a second closest prism which is second closest to the grating have temperature coefficients of refractive indices opposite in sign to each other, and an amount of change of an optical path length difference, in the expansion optical system, between a case in which a temperature difference in the second closest prism is 0.2° C. or less and a case in which the temperature difference is 0.5° C. or more and 10° C. or less is half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.

### BRIEF DESCRIPTION OF THE DRAWINGS

Embodiments of the present disclosure will be described below merely as examples with reference to the accompanying drawings.

FIG. 1 is a view schematically showing the configuration of a gas laser device according to a comparative example.

FIG. 2 is a view of a line narrowing module viewed from a Y direction.

FIG. 3 is a view of the line narrowing module viewed from an X direction.

FIG. 4 is a view showing an example of a fixing method of a prism.

FIG. 5 shows beam profiles and wavelength spectra at 5 minutes and 2 hours after start of laser oscillation.

FIG. 6 is a diagram defining orientation of each prism.

FIG. 7 is a view schematically showing distortion of a wavefront occurring at a third prism.

FIG. 8 is a view of the line narrowing module according to a first embodiment viewed from the Y direction.

FIG. 9 is a diagram defining an optical path length.

FIG. 10 is a view of the line narrowing module according to a modification viewed from the Y direction.

FIG. 11 is a diagram schematically showing a configuration example of an exposure apparatus.

### DESCRIPTION OF EMBODIMENTS

### Contents

1. Comparative example
   1.1 Gas laser device
      1.1.1 Configuration
      1.1.2 Operation
   1.2 Line narrowing module
   1.3 Problem
2. First Embodiment
   2.1 Configuration
   2.2 Operation
   2.3 Effect
3. Modifications of first embodiment
4. Electronic device manufacturing method

Hereinafter, an embodiment of the present disclosure will be described in detail with reference to the drawings. The embodiment described below show some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Gas Laser Device

### 1.1.1 Configuration

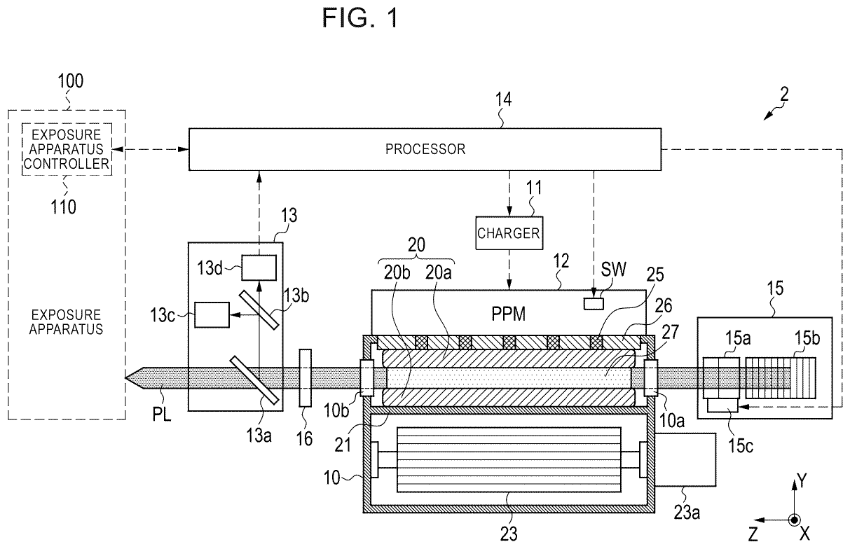

The configuration of a gas laser device 2 according to the comparative example will be described. FIG. 1 schematically shows the configuration of the gas laser device 2. The gas laser device 2 is a discharge-excitation-type gas laser device that discharges and excites a laser gas, and is, for example, an excimer laser device. The gas laser device 2 is an example of the “laser device” according to the technology of the present disclosure.

In FIG. 1, a travel direction of pulse laser light PL output from the gas laser device 2 is defined as a Z direction. A discharge direction to be described later is defined as a Y direction. A direction orthogonal to the Z direction and the Y direction is defined as an X direction. The pulse laser light PL is an example of the “laser light” according to the technology of the present disclosure.

The gas laser device 2 includes a laser chamber 10, a charger 11, a pulse power module (PPM) 12, a monitor module 13, a processor 14, and a laser resonator. The laser resonator is configured of a line narrowing module 15 and an output coupling mirror 16.

The laser chamber 10 is, for example, a metal container made of aluminum metal plated with nickel on the surface thereof. A main electrode 20, a ground plate 21, a fan 23, and the like are provided inside the laser chamber 10.

A laser gas containing fluorine as a laser medium is enclosed in the laser chamber 10. The laser gas includes, for example, argon, krypton, xenon, or the like as a rare gas, neon, helium, or the like as a buffer gas, and fluorine, chlorine, or the like as a halogen gas.

Further, an opening is formed in the laser chamber 10. An electrically insulating plate 26 in which a feedthrough 25 is embedded is attached to the laser chamber 10 via an O-ring (not shown) so as to close the opening. The PPM 12 is arranged on the electrically insulating plate 26. The laser chamber 10 is grounded.

The PPM 12 includes a charging capacitor (not shown) and is connected to the main electrode 20 via the feedthrough 25. The PPM 12 includes a switch SW for causing discharge to occur at the main electrode 20. The charger 11 is connected to the charging capacitor of the PPM 12.

The main electrode 20 is a pair of discharge electrodes consisting of a cathode electrode 20a and an anode electrode 20b. The cathode electrode 20a and the anode electrode 20b are arranged in the laser chamber 10 so that discharge surfaces of the both face each other. The space between the discharge surface of the cathode electrode 20a and the discharge surface of the anode electrode 20b is referred to as a discharge space 27. The cathode electrode 20a is supported by the electrically insulating plate 26 on a surface opposite to the discharge surface thereof, and is connected to the feedthrough 25. The anode electrode 20b is supported by the ground plate 21 on a surface opposite to the discharge surface thereof.

The fan 23 is a cross flow fan for circulating the laser gas in the laser chamber 10, and is arranged on the opposite side of the discharge space 27 with respect to the ground plate 21. A motor 23a for rotationally driving the fan 23 is connected to the laser chamber 10.

At an end part of the laser chamber 10, each of the windows 10a, 10b for outputting the pulse laser light PL generated in the laser chamber 10 to the outside is provided. The windows 10a, 10b are arranged such that the pulse laser light PL is incident at the Brewster angle. The laser chamber 10 is arranged such that the optical path of the optical resonator passes through the discharge space 27 and the windows 10a, 10b.

The line narrowing module 15 includes an expansion optical system 15a and a grating 15b. The expansion optical system 15a transmits the pulse laser light PL output from the laser chamber 10 through the window 10a toward the grating 15b while expanding the beam width of the pulse laser light PL.

The grating 15b is arranged in the Littrow arrangement so that the incident angle and the diffraction angle are the same. The grating 15b is a wavelength selection element that selectively extracts light having a wavelength near a particular wavelength in accordance with the diffraction angle. The spectral line width of the pulse laser light PL returning from the grating 15b to the laser chamber 10 via the expansion optical system 15a is line-narrowed.

Further, the line narrowing module 15 is provided with a rotation stage 15c that rotates one prism included in the expansion optical system 15a. Due to rotation of the prism by the rotation stage 15c, the incident angle of the pulse laser light PL incident on the grating 15b is changed.

The output coupling mirror 16 is a partial reflection mirror that transmits a part of the pulse laser light PL output from the laser chamber 10 through the window 10b and reflects the other part back into the laser chamber 10.

The pulse laser light PL output from the laser chamber 10 reciprocates between the line narrowing module 15 and the output coupling mirror 16. Most of P-polarized components of the pulse laser light PL are transmitted through the windows 10a, 10b without being Fresnel-reflected. On the other hand, most of S-polarized components are Fresnel-reflected and therefore attenuate while being transmitted through the windows 10a, 10b a plurality of times. The P-polarized components are amplified by being transmitted through the laser medium with little attenuation. Thus, the pulse laser light PL is output from the output coupling mirror 16 as linearly polarized light. The wavelength of the pulse laser light PL is in an ultraviolet range of 150 nm to 380 nm, and is, for example, an oscillation wavelength of an excimer laser device.

The monitor module 13 includes beam splitters 13a, 13b, a pulse energy measurement instrument 13c, and a spectrum measurement instrument 13d. The beam splitter 13a is arranged on the optical path of the pulse laser light PL output from the output coupling mirror 16, and reflects a part of the pulse laser light PL. The beam splitter 13b is arranged on the optical path of the pulse laser light PL reflected by the beam splitter 13a, and reflects a part of the pulse laser light PL.

The pulse energy measurement instrument 13c is arranged on the optical path of the pulse laser light PL reflected by the beam splitter 13b. The pulse energy measurement instrument 13c is, for example, a photodiode, and is configured to be capable of measuring the pulse energy of the pulse laser light PL output from the gas laser device 2.

The spectrum measurement instrument 13d is arranged on the optical path of the pulse laser light PL transmitted through the beam splitter 13b. The spectrum measurement instrument 13d is, for example, a monitor etalon spectrometer, and is configured to be capable of measuring the wavelength and the spectral line width of the pulse laser light PL by measuring the shape of the interference fringes with a line sensor or the like.

The charger 11 is a high voltage power source that supplies the charge voltage to the charging capacitor included in the PPM 12. The switch SW of the PPM 12 is controlled by the processor 14. When the switch SW is turned ON from OFF, the PPM 12 generates a high voltage pulse from the electric energy held in the charging capacitor and applies the high voltage pulse to the main electrode 20.

The processor 14 is a processing device that transmits and receives various signals to and from an exposure apparatus controller 110 provided in an exposure apparatus 100. For example, the exposure apparatus controller 110 transmits, to the processor 14, a target pulse energy of the pulse laser light PL to be output to the exposure apparatus 100, the measurement value of the wavelength, an oscillation trigger signal, and the like.

The processor 14 generally controls operation of components of the gas laser device 2 based on various signals transmitted from the exposure apparatus controller 110, the measurement value of the pulse energy, the measurement value of the wavelength, and the like.

The processor 14 functions as a controller of the gas laser device 2. For example, the processor 14 is a processing device including a storage device in which a control program is stored and a central processing unit (CPU) that executes the control program. The processor 14 is specifically configured or programmed to perform various processes included in the present disclosure. The storage device is a non-transitory computer-readable storage medium, and includes, for example, a memory that is a main storage device and a storage that is an auxiliary storage device. Here, the storage device may be a semiconductor memory, a hard disk drive (HDD) device, a solid state drive (SSD) device, or a combination thereof.

### 1.1.2 Operation

Next, operation of the gas laser device 2 according to the comparative example will be described. First, the processor 14 receives the target pulse energy, a target wavelength, and the oscillation trigger signal from the exposure apparatus controller 110. Here, the oscillation trigger signal is a signal for instructing the gas laser device 2 to output one pulse of the pulse laser light PL.

The processor 14 sets the charge voltage corresponding to the target pulse energy in the charger 11. The processor 14 operates the switch SW of the PPM 12 in synchronization with the oscillation trigger signal.

When the switch SW of the PPM 12 is turned ON from OFF, a voltage is applied between the cathode electrode 20a and the anode electrode 20b. Thus, when discharge occurs between the cathode electrode 20a and the anode electrode 20b, the laser gas in the discharge space 27 is excited to emit light.

The light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

The pulse laser light PL output from the output coupling mirror 16 enters the monitor module 13, is partially reflected by the beam splitter 13a, and is incident on the beam splitter 13b. The pulse laser light PL is split by the beam splitter 13b and enters each of the pulse energy measurement instrument 13c and the spectrum measurement instrument 13d. The pulse energy is measured by the pulse energy measurement instrument 13c, and the wavelength and the spectral line width are measured by the spectrum measurement instrument 13d. The pulse laser light PL transmitted through the beam splitter 13a enters the exposure apparatus 100.

The processor 14 controls the charge voltage so that the difference between the measurement value of the pulse energy and the target pulse energy approaches zero. Further, the processor 14 drives the rotation stage 15c and controls the incident angle of the pulse laser light PL incident on the grating 15b so that the difference between the measurement value of the wavelength and the target wavelength approaches zero.

### 1.2 Line Narrowing Module

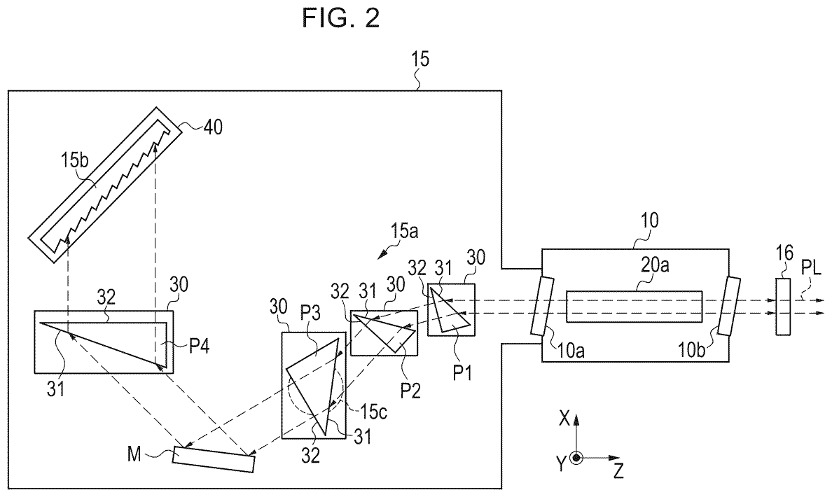

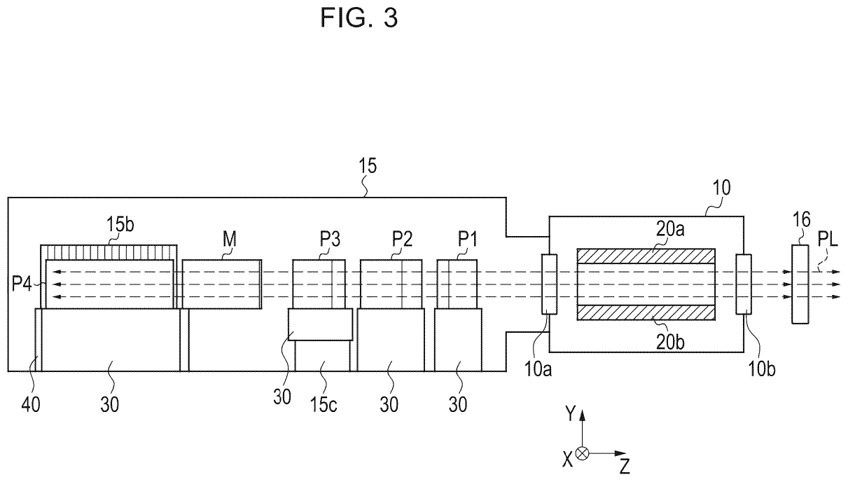

Next, the configuration of the line narrowing module 15 according to the comparative example will be described. FIG. 2 is a view of the line narrowing module 15 viewed from the Y direction. FIG. 3 is a view of the line narrowing module 15 viewed from the X direction.

The inside of a housing of the line narrowing module 15 is filled with a nitrogen gas. The expansion optical system 15a includes first to fourth prisms P1 to P4 and a mirror M. The first to fourth prisms P1 to P4 are arranged so that the pulse laser light PL output from the laser chamber 10 is transmitted through the first prism P1, the second prism P2, the third prism P3, and the fourth prism P4 in this order and is incident on the grating 15b. Further, the mirror M is arranged between the third prism P3 and the fourth prism P4, and reflects the pulse laser light PL transmitted through the third prism P3 so as to be incident on the fourth prism P4. Each time the pulse laser light PL is transmitted through the first to fourth prisms P1 to P4, the beam width thereof is expanded.

Each of the first to fourth prisms P1 to P4 is formed of calcium fluoride (CaF₂) and is held by a holder 30. The grating 15b is held by a holder 40. Each of the first to fourth prisms P1 to P4 includes two transmission surfaces 31, 32 through which the pulse laser light PL is transmitted. The transmission surfaces 31, 32 are parallel to the Y direction. Each of the first to fourth prisms P1 to P4 is, for example, a triangular prism.

Each of the first to fourth prisms P1 to P4 is arranged so that the travel direction of the pulse laser light PL being transmitted through the transmission surface 31 is non-perpendicular to the transmission surface 31, and the travel direction of the pulse laser light PL being transmitted through the transmission surface 32 is perpendicular to the transmission surface 32. For example, the incident angle of the pulse laser light PL with respect to the transmission surface 31 is larger than the Brewster angle. The pulse laser light PL is refracted at the transmission surface 31, and the pulse laser light PL travels substantially straight at the transmission surface 32. The transmission surface 31 is coated with a film that suppresses reflection of the P-polarized components of the pulse laser light PL. The transmission surface 32 is coated with a film that suppresses reflection of the pulse laser light PL.

When the volumes of the first to fourth prisms P1 to P4 are represented by VP1 to VP4, respectively, three magnitude relations of “VP1<VP2<VP3<VP4”, “VP1=VP2<VP3<VP4”, or “VP1=VP2=VP3<VP4” may be satisfied. In the example shown in FIGS. 2 and 3, the relationship of “VP1<VP2<VP3<VP4” is satisfied.

The holder 30 holding the third prism P3 is arranged on the above-described rotation stage 15c. The rotation stage 15c rotates the third prism P3 about an axis parallel to the Y direction.

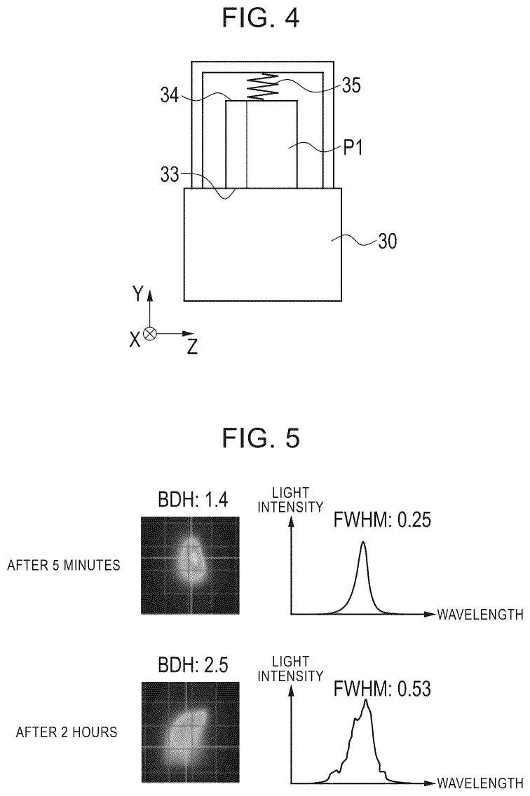

Each of the first to fourth prisms P1 to P4 has a lower surface side held by the holder 30, and an upper surface side supported by a support member 35. For example, as shown in FIG. 4, the first prism P1 is held by the holder 30 with the entire lower surface 33 being in contact thereto, and is supported by the support member 35 with a part of the upper surface 34 being in contact thereto. Thus, in each of the first to fourth prisms P1 to P4, the contact area with respect to the holder 30 on the lower surface side is larger than the contact area with respect to the support member 35 on the upper surface side.

### 1.3 Problem

Next, a problem of the gas laser device 2 according to the comparative example will be described. The applicant has confirmed that, when operation of the gas laser device 2 is started, the beam profile and the wavelength spectrum of the pulse laser light PL change in accordance with elapsed time from start of laser oscillation.

FIG. 5 shows the beam profiles and the wavelength spectra at 5 minutes and 2 hours after the start of laser oscillation. Comparison of the beam profiles after 5 minutes and 2 hours shows that the beam divergence increases after a long time elapses. BDH shown in FIG. 5 shows the beam divergence in the X direction. The beam divergence refers to a width of a region in which the light intensity is higher than a certain ratio with respect to a peak value.

Further, comparison of the wavelength spectra after 5 minutes and 2 hours shows that the spectral line width increases after a long time elapses. FWHM shown in FIG. 5 is an index of the spectral line width and is the full width at half maximum of the wavelength spectrum.

It is considered that deterioration of the beam divergence and the spectral line width is caused by distortion of a wavefront of the pulse laser light PL due to thermal difference occurring in each of the first to fourth prisms P1 to P4 by laser oscillation.

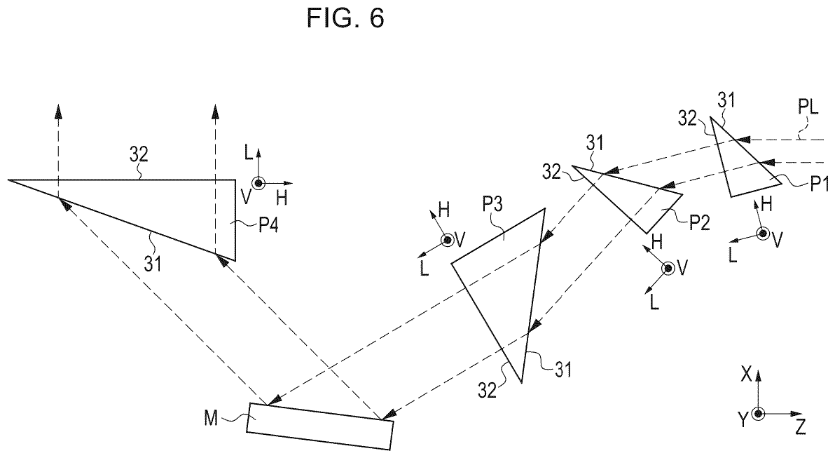

The applicant has evaluated the cause of distortion of the wavefront of the pulse laser light PL, which will be described below. First, as shown in FIG. 6, for each of the first to fourth prisms P1 to P4, the Y direction is defined as a V direction, a direction perpendicular to the transmission surface 32 is defined as an L direction, and a direction orthogonal to both the V direction and the L direction is defined as an H direction. The H direction is an expansion direction of the beam width.

Each of the first to fourth prisms P1 to P4 absorbs a part of the pulse laser light PL when the pulse laser light PL is transmitted therethrough, so that heat is generated. In each of the first to fourth prisms P1 to P4, the portion in contact to the holder 30 or the support member 35 are cooled via the holder 30 or the support member 35, and other portions are cooled via the nitrogen gas. Cooling via the holder 30 or the support member 35 has a higher cooling efficiency than cooling via the nitrogen gas. Further, the holder 30 and the support member 35 differ in the contact area and the heat capacity for each of the first to fourth prisms P1 to P4. Accordingly, when the elapsed time from the start of laser oscillation becomes long, temperature difference occurs in each of the first to fourth prisms P1 to P4. As described above, since the contact area and the heat capacity of the holder 30 are larger than those of the support member 35, each of the first to fourth prisms P1 to P4 has a higher temperature on the upper surface side than on the lower surface side, and a temperature gradient occurs in the V direction.

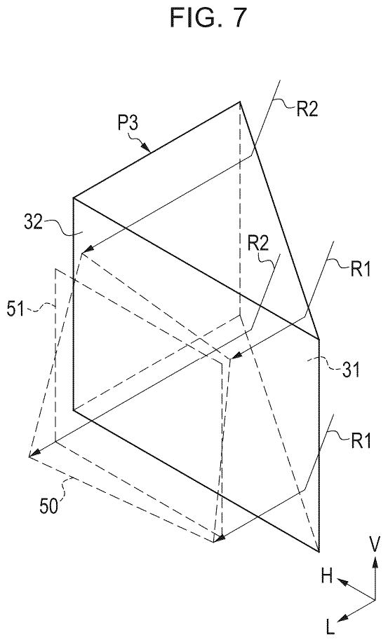

FIG. 7 schematically shows distortion of the wavefront occurring at the third prism P3. A light ray at one end of the beam width of the pulse laser light PL in the H direction transmitted through the third prism P3 is defined as a first light ray R1, and a light ray at the other end is defined as a second light ray R2. Since the second light ray R2 is transmitted through a thicker portion of the third prism P3 than the first light ray R1, a transmission length of the second light ray R2 is longer than a transmission length of the first light ray R1. Thus, the transmission lengths are different in the H direction. Here, the transmission length refers to a physical distance of the transmission optical path through the prism.

Further, when the third prism P3 has a thermal gradient in the V direction, an optical path length changes in the V direction. Here, the optical path length refers to an optical distance obtained by multiplying the transmission length by a refractive index. Since the third prism P3 is formed of calcium fluoride having a negative temperature coefficient of the refractive index, the higher the temperature is, the lower the refractive index is. Therefore, the optical path length is shorter at the upper portion than at the lower portion of the third prism P3. Therefore, since the optical path lengths of the first light ray R1 and the second light ray R2 are different in the V direction, and the transmission length of the second light ray R2 is longer than that of the first light ray R1, the change in the optical path length is larger for the second light ray R2 than for the first light ray R1.

As a result, distortion of the wavefront of the pulse laser light PL transmitted through the third prism P3 occurs. In FIG. 7, a wavefront 50 schematically shows the wavefront in a case in which distortion is occurring. A wavefront 51 schematically shows the wavefront in a case in which distortion is not occurring. For example, the wavefront 51 after 5 minutes from the start of laser oscillation changes to be the wavefront 50 after 2 hours due to distortion occurrence.

When the pulse laser light PL is transmitted through the first prism P1, the second prism P2, and the fourth prism P4, distortion of the wavefront similarly occurs. Since the larger the beam width of the incident pulse laser light PL in the H direction is, the larger the influence on distortion of the wavefront is, distortion of the wavefront occurs more greatly at the third prism P3 and the fourth prism P4 than at the first prism P1 and the second prism P2. It is considered that such distortion of the wavefront results in deterioration of the beam divergence and the spectral line width.

Accordingly, an object of the present disclosure is to provide a line narrowing module, a laser device, and an electronic device manufacturing method that can suppress deterioration of the beam divergence and the spectral line width due to distortion of the wavefront.

### 2. First Embodiment

### 2.1 Configuration

The gas laser device 2 according to a first embodiment of the present disclosure has a configuration similar to that of the gas laser device 2 according to the comparative example except that the configuration of the line narrowing module 15 is different.

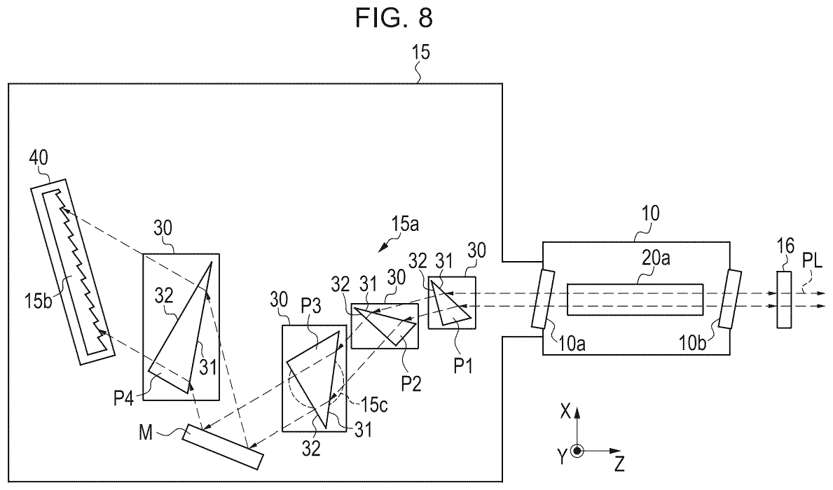

FIG. 8 is a view of the line narrowing module 15 according to the first embodiment viewed from the Y direction. In the present embodiment, among the first to fourth prisms P1 to P4, the third prism P3 and the fourth prism P4, which are considered to have a large influence on the distortion of the wavefront, are formed of materials having temperature coefficients of the refractive indices opposite in sign to each other, thereby suppressing the change in the optical path length due to a temperature change. The fourth prism P4 is the “first closest prism” that is closest to the grating 15b. The third prism P3 is the “second closest prism” that is second-closest to the grating 15b.

Examples of a material having a positive temperature coefficient of the refractive index include synthetic quartz (SiO₂) and sapphire. Examples of a material having a negative temperature coefficient of the refractive index include calcium fluoride (CaF₂) and quartz. The temperature coefficient of the refractive index of synthetic quartz is 1.02×10⁻⁵. The temperature coefficient of the refractive index of calcium fluoride is −1.08×10⁻⁵.

Since a transmission cross-sectional area of the pulse laser light is smaller at the third prism P3 than at the fourth prism P4, higher resistance with respect to the pulse laser light PL is required for the third prism P3 than the fourth prism P4. Therefore, in the present embodiment, the third prism P3 is formed of calcium fluoride, which has high resistance with respect to the pulse laser light PL, and the fourth prism P4 is formed of synthetic quartz.

Since each of the first prism P1 and the second prism P2 has a transmission cross-sectional area smaller than the third prism P3, the first prism P1 and the second prism P2 are preferably formed of calcium fluoride.

The sum of optical path lengths of the first light ray R1 in the third prism P3 and the fourth prism P4 is defined as a first total optical path length, the sum of optical path lengths of the second light ray R2 in the third prism P3 and the fourth prism P4 is defined as a second total optical path length, and a difference between the first total optical path length and the second total optical path length is defined as an optical path length difference. In the present embodiment, the amount of change in the optical path length difference between a case in which the elapsed time from the start of laser oscillation is in a first time period and a case in which the elapsed time is in a second time period is set to be less than a reference value. Here, the reference value is a value obtained by multiplying the wavelength of the pulse laser light PL by ½.

The first time period is a time period in which the temperature difference in the third prism P3 is 0.2° C. or less and is, for example, 5 minutes or less. The second time period is a time period in which the temperature difference in the third prism P3 is 0.5° C. or more and 10° C. or less and is, for example, longer than 5 minutes and includes 2 hours. The temperature difference in the prism refers to a value obtained by subtracting the minimum temperature from the maximum temperature in the prism.

As described above, the first light ray R1 and the second light ray R2 are the light lay at one end and the light lay at the other end of the beam width of the pulse laser light PL in the H direction, respectively. In the present embodiment, it is assumed that the first light ray R1 and the second light ray R2 are two light lays passing through the same position in the V direction.

In the present embodiment, to set the above-described amount of change in the optical path length equal to or less the reference value, the third prism P3 and the fourth prism P4 are arranged so that the transmission length of the first light ray R1 is shorter than the transmission length of the second light ray R2 in the third prism P3 and the fourth prism P4. Here, the third prism P3 and the fourth prism P4 may be arranged so that the transmission length of the first light ray R1 is longer than the transmission length of the second light ray R2 in the third prism P3 and the fourth prism P4.

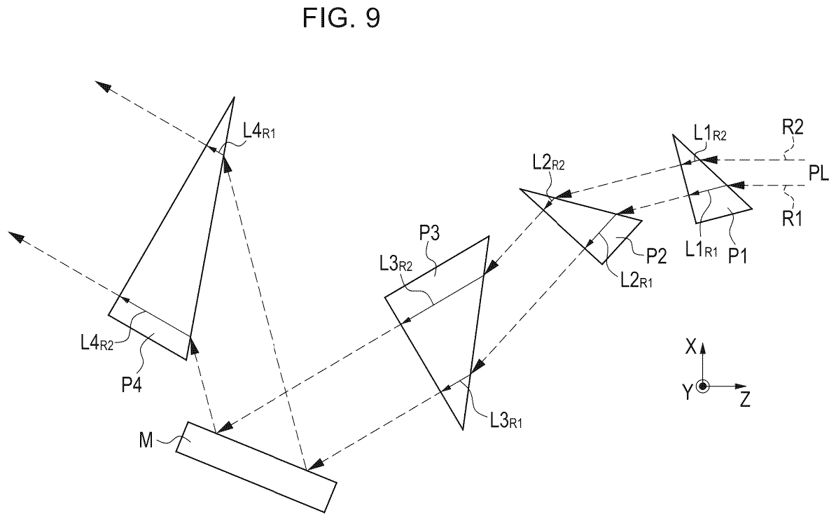

Conditions for setting the amount of change of the optical path length difference equal to or less than the reference value will be described in more detail using FIG. 9. As shown in FIG. 9, the transmission length of the first light ray R1 in the first prism P1 is represented by L1_{R1}, the transmission length thereof in the second prism P2 is represented by L2_{R1}, the transmission length thereof in the third prism P3 is represented by L3_{R1}, and the transmission length thereof in the fourth prism P4 is represented by L4_{R1}. Further, the transmission length of the second light ray R2 in the first prism P1 is represented by L1_{R2}, the transmission length thereof in the second prism P2 is represented by L2_{R2}, the transmission length thereof in the third prism P3 is represented by L3_{R2}, and the transmission length thereof in the fourth prism P4 is represented by L4_{R2}.

Further, the first total optical path length in the first time period is represented by LC_{R1}, the second total optical path length in the first time period is represented by LC_{R2}, the first total optical path length in the second time period is represented by LH_{R1}, and the second total optical path length in the second time period is represented by LH_{R2}. Further, the refractive index of the third prism P3 in the first time period is represented by n₁, and the refractive index of the fourth prism P4 in the first time period is represented by n₂.

The first total optical path length LC_{R1} in the first time period is expressed by the following Expression (1).

$$\begin{matrix}[ Expression 1 ] & \\ {LC}_{R 1} = L {3}_{R 1} \times {n}_{1} + L {4}_{R 1} \times {n}_{2} & ( 1 )\end{matrix}$$

The second total optical path length LC_{R2} in the first time period is expressed by the following Expression (2).

$$\begin{matrix}[ Expression 2 ] & \\ {LC}_{R 2} = L {3}_{R 2} \times {n}_{1} + L {4}_{R 2} \times {n}_{2} & ( 2 )\end{matrix}$$

When the optical path length difference in the first time period is represented by ΔLC, the optical path length difference ΔLC is expressed by the following Expression (3).

$$\begin{matrix}[ Expression 3 ] & \\ Δ LC = {LC}_{R 2} - {LC}_{R 1} & ( 3 )\end{matrix}$$

The temperature coefficient of the refractive index n₁ of the third prism P3 is represented by dn₁/dT, and the temperature coefficient of the refractive index n₂ of the fourth prism P4 is represented by dn₂/dT. Further, in the second time period, the temperature change from the first time period at a transmission position of the first light ray R1 in the third prism P3 is represented by ΔT₃₁, and the temperature change from the first time period at a transmission point of the first light ray R1 in the fourth prism P4 is represented by ΔT₄₁. Further, in the second time period, the temperature change from the first time period at a transmission position of the second light ray R2 in the third prism P3 is represented by ΔT₃₂, and the temperature change from the first time period at a transmission point of the second light ray R2 in the fourth prism P4 is represented by ΔT₄₂.

The first total optical path length LH_{R1} in the second time period is expressed by the following Expression (4).

$$\begin{matrix}[ Expression 4 ] & \\ {LH}_{R 1} = L {3}_{R 1} \times ( {n}_{1} + \frac{{dn}_{1}}{dT} \times Δ {T}_{31} ) + L {4}_{R 1} \times ( {n}_{2} + \frac{{dn}_{2}}{dT} \times Δ {T}_{41} ) & ( 4 )\end{matrix}$$

The second total optical path length LH_{R2} in the second time period is expressed by the following Expression (5).

$$\begin{matrix}[ Expression 5 ] & \\ {LH}_{R 2} = L {3}_{R 2} \times ( {n}_{1} + \frac{{dn}_{1}}{dT} \times Δ {T}_{32} ) + L {4}_{R 2} \times ( {n}_{2} + \frac{{dn}_{2}}{dT} \times Δ {T}_{42} ) & ( 5 )\end{matrix}$$

When the optical path length difference in the second time period is represented by ΔLH, the optical path length difference ΔLH is expressed by the following Expression (6).

$$\begin{matrix}[ Expression 6 ] & \\ Δ LH = {LH}_{R 2} - {LH}_{R 1} & ( 6 )\end{matrix}$$

In the present embodiment, the transmission lengths L3_{R1}, L3_{R2}, L4_{R1}, L4_{R2} are set so as to satisfy the following Expression (7). Here, A is the wavelength of the pulse laser light PL, and λ/2 is the reference value described above.

$$\begin{matrix}[ Expression 7 ] & \\ \vert Δ LH - Δ LC \vert < λ / 2 & ( 7 )\end{matrix}$$

The above Expression (7) is modified to the following Expression (8).

$$\begin{matrix}[ Expression 8 ] & \\ & ( 8 )\end{matrix}$$

$$\vert ( L {3}_{R 2} \times Δ {T}_{32} - L {3}_{R 1} \times Δ {T}_{31} ) \times \frac{{dn}_{1}}{dT} + ( L {4}_{R 2} \times Δ {T}_{42} - L {4}_{R 1} \times Δ {T}_{41} ) \times \frac{{dn}_{2}}{dT} \vert < λ / 2$$

To satisfy the above Expression (8) regardless of the temperature change, it is necessarily that the temperature coefficient dn₁/dT and the temperature coefficient dn₂/dT are opposite in sign to each other. In addition, it is preferable that either of the relationship of “L3R1<L3R2 and L4R1<L4R2” or the relationship of “L3R1>L3R2 and L4R1>L4R2” is satisfied.

The temperature changes ΔT₃₁, ΔT₃₂, ΔT₄₁, ΔT₄₂ vary depending on the fixing methods of the third prism P3 and the fourth prism P4, the pulse energy of the pulse laser light PL transmitted therethrough, and the like.

### 2.2 Operation

Operation of the gas laser device 2 according to the present embodiment is similar to that of the comparative example except that the effect of the line narrowing module 15 is different.

The fourth prism P4 and the third prism P3 are formed of materials having the temperature coefficients of the refractive indices opposite in sign to each other, and the transmission lengths L3_{R1}, L3_{R2}, L4_{R1}, L4_{R2} are set so as to satisfy the above Expression (7), thereby suppressing the change in the optical path length due to the temperature change.

### 2.3 Effect

According to the present embodiment, since the change in the optical path length due to the temperature change is suppressed, distortion of the wavefront is suppressed. Accordingly, deterioration of the beam divergence and the spectral line width can be suppressed.

### 3. Modifications of First Embodiment

Various modifications of the first embodiment will be described below.

In the above embodiment, the sum of the optical path lengths of the first light ray R1 in the third prism P3 and the fourth prism P4 is set as the first total optical path length, but the sum of the optical path lengths of the first light ray R1 in the first to fourth prisms P1 to P4 may be set as the first total optical path length. Similarly, the sum of the optical path lengths of the second light ray R2 in the first to fourth prisms P1 to P4 may be set as the second total optical path length.

In this case, the above Expressions (1) and (2) are replaced with the following Expressions (1a) and (2a).

$$\begin{matrix}[ Expression 9 ] & \\ {LC}_{R 1} = ( L {1}_{R 1} + L {2}_{R 1} + L {3}_{R 1} ) \times {n}_{1} + L {4}_{R 1} \times {n}_{2} & ( 1 a )\end{matrix}$$

$$\begin{matrix}[ Expression 10 ] & \\ {LC}_{R 2} = ( L {1}_{R 2} + L {2}_{R 2} + L {3}_{R 2} ) \times {n}_{1} + L {4}_{R 2} \times {n}_{2} & ( 2 a )\end{matrix}$$

The above Expressions (4) and (5) are replaced with the following Expressions (4a) and (5a). Here, the temperature change from the first time period at the transmission position of the first light ray R1 in the first prism P1 is represented by ΔT₁₁, and the temperature change from the first time period at the transmission point of the first light ray R1 in the second prism P2 is represented by ΔT₂₁. Further, the temperature change from the first time period at the transmission position of the second light ray R2 in the first prism P1 is represented by ΔT₁₂, and the temperature change from the first time period at the transmission point of the second light ray R2 in the second prism P2 is represented by ΔT₂₂.

$$\begin{matrix}[ Expression 11 ] & \\ & ( 4 a )\end{matrix}$$

$${LH}_{R 1} = L {1}_{R 1} \times {n}_{1} \times \frac{{dn}_{1}}{dT} \times Δ {T}_{11} + L {2}_{R 1} \times {n}_{1} \times \frac{{dn}_{1}}{dT} \times Δ {T}_{21} + L {3}_{R 1} \times {n}_{1} \times \frac{{dn}_{1}}{dT} \times Δ {T}_{31} + L {4}_{R 1} \times {n}_{2} \times \frac{{dn}_{2}}{dT} \times Δ {T}_{41}$$

$$\begin{matrix}[ Expression 12 ] & \\ & ( 5 a )\end{matrix}$$

$${LH}_{R 2} = L {1}_{R 2} \times {n}_{1} \times \frac{{dn}_{1}}{dT} \times Δ {T}_{12} + L {2}_{R 2} \times {n}_{1} \times \frac{{dn}_{1}}{dT} \times Δ {T}_{22} + L {3}_{R 2} \times {n}_{1} \times \frac{{dn}_{1}}{dT} \times Δ {T}_{32} + L {4}_{R 2} \times {n}_{2} \times \frac{{dn}_{2}}{dT} \times Δ {T}_{42}$$

As a result, the above expression (8) becomes the following expression (8a).

$$\begin{matrix}[ Expression 13 ] & \\ & ( 8 a )\end{matrix}$$

$$\vert ( L {1}_{R 2} \times Δ {T}_{12} - L {1}_{R 1} \times Δ {T}_{11} + L {2}_{R 2} \times Δ {T}_{22} - L {2}_{R 1} \times Δ {T}_{21} + L {3}_{R 2} \times Δ {T}_{32} - L {3}_{R 1} \times Δ {T}_{31} ) \times \frac{{dn}_{1}}{dT} + ( L {4}_{R 2} \times Δ {T}_{42} - L {4}_{R 1} \times Δ {T}_{41} ) \times \frac{{dn}_{2}}{dT} \vert < λ / 2$$

In the above Expression (8a), in addition to the temperature changes of the third prism P3 and the fourth prism P4, influence due to the temperature changes of the first prism P1 and the second prism P2 are taken into account. Therefore, by setting the optical path lengths of the first light ray R1 and the second light ray R2 transmitted through the first to fourth prisms P1 to P4 so as to satisfy the above Expression (8a), it is possible to suppress deterioration of the beam divergence and the spectral line width with higher accuracy.

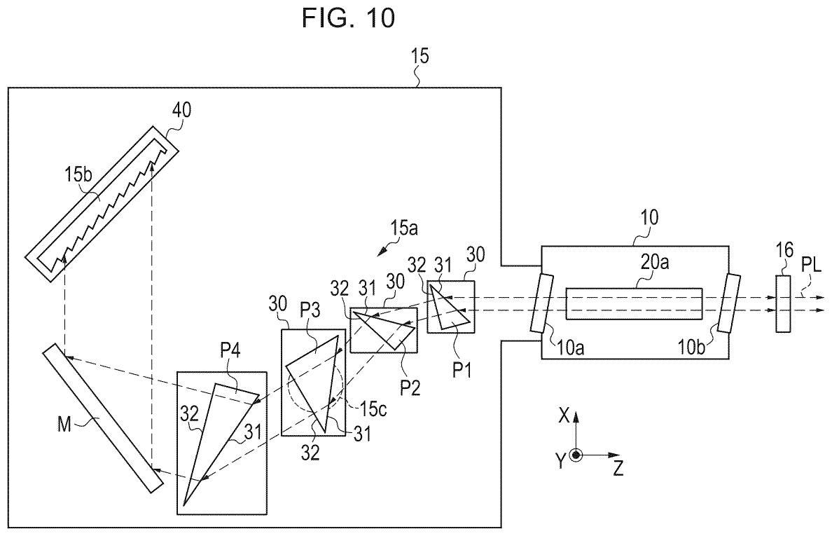

In the above embodiment, the mirror M is arranged between the third prism P3 and the fourth prism P4. However, as shown in FIG. 10, the mirror M may be arranged between the fourth prism P4 and the grating 15b. In this case, the mirror M reflects the pulse laser light PL transmitted through the fourth prism P4 so as to be incident on the grating 15b. The other configuration of the line narrowing module 15 shown in FIG. 10 is similar to that of the above-described embodiment.

In the above embodiment, the line narrowing module 15 includes four prisms, but may include five or more prisms. The line narrowing module 15 is only required to be configured to include a plurality of prisms.

### 4. Electronic Device Manufacturing Method

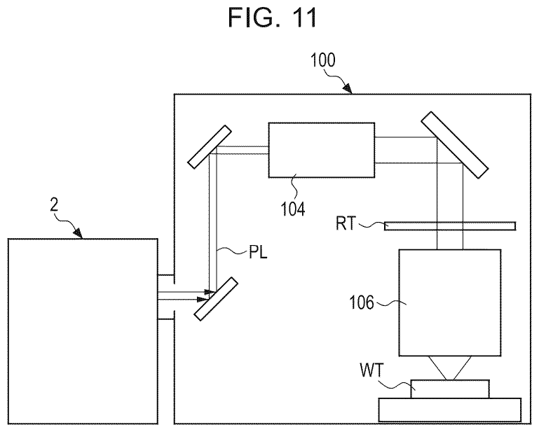

FIG. 11 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Here, not limited to the manufacturing of an electronic device, the gas laser device 2 may be used for laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A line narrowing module configured to line-narrow pulse laser light having a wavelength in an ultraviolet range, the line narrowing module comprising:
a grating configured to reflect pulse laser light incident thereon; and
an expansion optical system including a plurality of prisms and configured to cause the pulse laser light to be incident on the grating while expanding a beam width of the pulse laser light,
a first closest prism which is closest to the grating and a second closest prism which is second closest to the grating, in the expansion optical system, having temperature coefficients of refractive indices opposite in sign to each other, and
an amount of change of an optical path length difference, in the expansion optical system, between a case in which a temperature difference in the second closest prism is 0.2° C. or less and a case in which the temperature difference is 0.5° C. or more and 10° C. or less being half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.

2. The line narrowing module according to claim 1,
wherein an optical path length of the first light ray in the first closest prism is shorter than an optical path length of the second light ray in the first closest prism, and
an optical path length of the first light ray in the second closest prism is shorter than an optical path length of the second light ray in the second closest prism.

3. The line narrowing module according to claim 1,
wherein the first closest prism is formed of a material having a positive temperature coefficient of the refractive index, and
the second closest prism is formed of a material having a negative temperature coefficient of the refractive index.

4. The line narrowing module according to claim 3,
wherein the first closest prism is formed of synthetic quartz, and
the second closest prism is formed of calcium fluoride.

5. The line narrowing module according to claim 1,
wherein the expansion optical system includes a mirror arranged between the first closest prism and the second closest prism.

6. The line narrowing module according to claim 1,
wherein the expansion optical system includes a mirror arranged between the grating and the first closest prism.

7. The line narrowing module according to claim 1,
wherein the plurality of prisms are four prisms.

8. A line narrowing module configured to line-narrow pulse laser light having a wavelength in an ultraviolet range, the line narrowing module comprising:
a grating configured to reflect pulse laser light incident thereon; and
an expansion optical system including a plurality of prisms and configured to cause the pulse laser light to be incident on the grating while expanding a beam width of the pulse laser light,
a first closest prism which is closest to the grating and a second closest prism which is second closest to the grating, in the expansion optical system, having temperature coefficients of refractive indices opposite in sign to each other, and
an amount of change of an optical path length difference, in the expansion optical system, between a case in which a temperature difference in the second closest prism is 0.2° C. or less and a case in which the temperature difference is 0.5° C. or more and 10° C. or less being half or less of the wavelength of the pulse laser light, as defining a light ray at one end of the pulse laser light in an expansion direction as a first light ray, a light ray at the other end as a second light ray, and a difference between a sum of optical path lengths of the first light ray in the plurality of prisms and a sum of optical path lengths of the second light ray in the plurality of prisms as the optical path length difference.

9. The line narrowing module according to claim 8,
wherein an optical path length of the first light ray in the first closest prism is shorter than an optical path length of the second light ray in the first closest prism, and
an optical path length of the first light ray in the second closest prism is shorter than an optical path length of the second light ray in the second closest prism.

10. The line narrowing module according to claim 8,
wherein the first closest prism is formed of a material having a positive temperature coefficient of the refractive index, and
the second closest prism is formed of a material having a negative temperature coefficient of the refractive index.

11. The line narrowing module according to claim 10,
wherein the first closest prism is formed of synthetic quartz, and
the second closest prism is formed of calcium fluoride.

12. The line narrowing module according to claim 8,
wherein the expansion optical system includes a mirror arranged between the first closest prism and the second closest prism.

13. The line narrowing module according to claim 8,
wherein the expansion optical system includes a mirror arranged between the grating and the first closest prism.

14. The line narrowing module according to claim 8,
wherein the plurality of prisms are four prisms.

15. A laser device comprising:
a line narrowing module configured to line-narrow pulse laser light having a wavelength in an ultraviolet range;
an output coupling mirror; and
a laser chamber including a pair of discharge electrodes and arranged on an optical path of an optical resonator configured by the line narrowing module and the output coupling mirror,
the line narrowing module including:
a grating configured to reflect pulse laser light incident thereon; and
an expansion optical system including a plurality of prisms and configured to cause the pulse laser light to be incident on the grating while expanding a beam width of the pulse laser light,
a first closest prism which is closest to the grating and a second closest prism which is second closest to the grating, in the expansion optical system, having temperature coefficients of refractive indices opposite in sign to each other, and
an amount of change of an optical path length difference, in the expansion optical system, between a case in which a temperature difference in the second closest prism is 0.2° C. or less and a case in which the temperature difference is 0.5° C. or more and 10° C. or less being half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.

16. An electronic device manufacturing method, comprising:
generating pulse laser light using a laser device;
outputting the pulse laser light to an exposure apparatus; and
exposing a photosensitive substrate to the pulse laser light in the exposure apparatus to manufacture an electronic device,
the laser device including:
a line narrowing module configured to line-narrow pulse laser light having a wavelength in an ultraviolet range;
an output coupling mirror; and
a laser chamber including a pair of discharge electrodes and arranged on an optical path of an optical resonator configured by the line narrowing module and the output coupling mirror, and
the line narrowing module including:
a grating configured to reflect the pulse laser light incident thereon; and
an expansion optical system including a plurality of prisms and configured to cause the pulse laser light to be incident on the grating while expanding a beam width of the pulse laser light,
a first closest prism which is closest to the grating and a second closest prism which is second closest to the grating, in the expansion optical system, having temperature coefficients of refractive indices opposite in sign to each other, and
an amount of change of an optical path length difference, in the expansion optical system, between a case in which a temperature difference in the second closest prism is 0.2° C. or less and a case in which the temperature difference is 0.5° C. or more and 10° C. or less being half or less of the wavelength of the pulse laser light, as defining a light ray at one end of the pulse laser light in an expansion direction as a first light ray, a light ray at the other end as a second light ray, and a difference between a sum of optical path lengths of the first light ray in the first closest prism and the second closest prism and a sum of optical path lengths of the second light ray in the first closest prism and the second closest prism as the optical path length difference.
